(19) United States
(12) Patent Application Publication
(10) Pub. No.: US 2026/0182212 A1
(43) Pub. Date: Jun. 25, 2026

(54) DISPLAY DEVICE

(71) Applicant: LG Display Co., Ltd., Seoul (KR)

(72) Inventors: JuWon JEON, Seoul (KR); Sukhyun KANG, Goyang-si (KR); Wonyeol CHOI, Paju-si (KR); Seonhee LEE, Paju-si (KR)

(73) Assignee: LG Display Co., Ltd., Seoul (KR)

(21) Appl. No.: 19/222,507

(22) Filed: May 29, 2025

(30) Foreign Application Priority Data
Dec. 24, 2024 (KR) 10-2024-0195995

(51) Int. Cl. H10K 59/80

(52) U.S. Cl. CPC H10K 59/873

(57) ABSTRACT

A display device of the present specification includes a substrate including a display area, an optical area disposed in the display area and including a through-hole, and a non-display area, a plurality of light-emitting elements disposed in the display area and including a first electrode, an organic layer, and a second electrode, a capping layer disposed on the plurality of light-emitting elements, an encapsulation unit disposed on the capping layer, and at least one stopper disposed in the optical area, in which at least one stopper includes a first layer disposed on the same layer as the organic layer, a second layer disposed on the same layer as the second electrode and a third layer disposed on the same layer as the capping layer. Therefore, at least one stopper may control a flow of an organic encapsulation layer included in the encapsulation unit in the optical area.

### CROSS-REFERENCE TO RELATED APPLICATIONS

This application claims the priority of Korean Patent Application No. 10-2024-0195995 filed on Dec. 24, 2024, in the Korean Intellectual Property Office, the disclosure of which is incorporated herein by reference.

### BACKGROUND

### Technical Field

The present specification relates to a display device, and more particularly, to a display device capable of controlling a flow of an organic encapsulation layer in an area in which a through-hole is disposed.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### BRIEF SUMMARY

The display device according to some embodiments of the present disclosure includes a multilayer stopper structure in an optical area containing a through-hole, designed to control the flow of an organic encapsulation layer and eliminate the need for conventional dam structures. Formed by laser irradiation, each stopper comprises layers made of the same materials as the organic layer, second electrode, and capping layer. The laser patterning creates upwardly curved ends, enabling the stopper to guide and block the encapsulation material effectively, reducing optical area size and improving encapsulation coverage without overflow.

Additionally, disconnecting the organic light-emitting layer around the through-hole blocks potential moisture and oxygen ingress paths, enhancing device reliability. An opening in a nearby insulation layer further prevents crack propagation from the through-hole into the display area. Collectively, these structural features enable compact integration of optical elements such as cameras or sensors within the display area, while enhancing durability and maintaining high display performance. The design allows for reduced optical area size, improved encapsulation integrity, and increased resistance to moisture ingress and mechanical damage.

Various embodiments of the present specification provide a display device capable of controlling a flow of an organic encapsulation layer in an area in which a through-hole is disposed.

Various embodiments of the present specification provide a display device capable of inhibiting the permeation of moisture from the outside through a through-hole, thereby inhibiting damage to a light-emitting element.

Various embodiments of the present specification provide a display device capable of ensuring a margin of an optical area.

Technical benefits of the present disclosure are not limited to the above-mentioned benefits, and other benefits, which are not mentioned above, can be clearly understood by those skilled in the art from the following descriptions.

A display device according to an embodiment of the present specification includes a substrate including a display area, an optical area disposed in the display area and including a through-hole, and a non-display area configured to surround the display area, a plurality of light-emitting elements disposed in the display area on the substrate and including a first electrode, an organic layer on the first electrode, and a second electrode on the organic layer, a capping layer configured to cover the plurality of light-emitting elements, an encapsulation unit configured to cover the capping layer, and at least one stopper disposed in the optical area on the substrate, in which at least one stopper includes a first layer disposed on the same layer as the organic layer and made of the same material as the organic layer, a second layer disposed on the first layer, disposed on the same layer as the second electrode, and made of the same material as the second electrode, and a third layer disposed on the second layer, disposed on the same layer as the capping layer, and made of the same material as the capping layer.

A display device according to another embodiment of the present specification includes a substrate including a display area, an optical area disposed in the display area and including a through-hole, and a non-display area configured to surround the display area, a plurality of light-emitting elements disposed in the display area on the substrate and including a first electrode, an organic layer on the first electrode, and a second electrode on the organic layer, a capping layer configured to cover the plurality of light-emitting elements, and at least one stopper disposed in the optical area on the substrate, in which at least one stopper includes a first layer disposed on the same layer as the organic layer and made of the same material as the organic layer, a second layer disposed on the first layer, disposed on the same layer as the second electrode, and made of the same material as the second electrode, and a third layer disposed on the second layer, disposed on the same layer as the capping layer, and made of the same material as the capping layer, and in which two opposite ends of at least one stopper have shapes curved upward.

Other detailed matters of the exemplary embodiments are included in the detailed description and the drawings.

According to the display device of the present specification, at least one stopper is disposed in the optical area, such that the flow of the organic encapsulation layer to the optical area may be controlled.

According to the display device of the present specification, the organic layers of the plurality of light-emitting elements in the optical area are disconnected, such that the transmission route for the permeated moisture may be disconnected even though moisture permeates from the through-hole, which may suppress the degradation of the plurality of light-emitting elements.

The display device of the present specification may ensure the margin of the optical area by removing or minimizing the dam in the optical area.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram for explaining a display device according to an embodiment of the present specification;

FIG. 2 is a view schematically illustrating a circuit configuration of a subpixel according to the embodiment of the present specification;

FIG. 3 is a top plan view of the display device according to the embodiment of the present specification;

FIG. 4 is a cross-sectional view taken along line IV-IV′ in FIG. 3;

FIG. 5 is a cross-sectional view taken along line V-V′ in FIG. 3;

FIGS. 6A and 6B are Scanning Electron Microscope (SEM) images of a stopper according to the embodiment of the present specification;

FIG. 7 is a cross-sectional view of a display device according to another embodiment of the present specification; and

FIGS. 8A and 8B are SEM images of a stopper according to another embodiment of the present specification.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

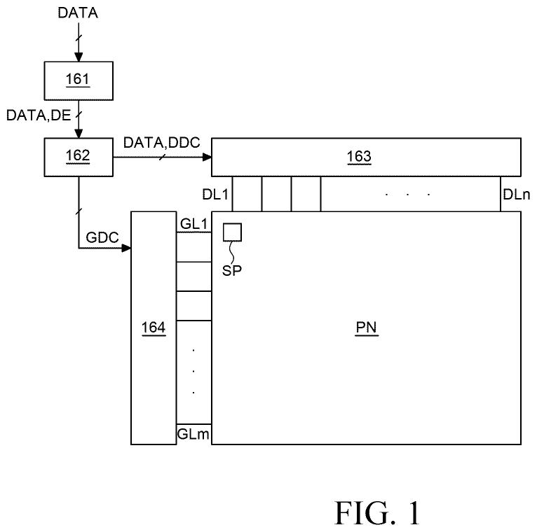

FIG. 1 is a block diagram of a display device according to an embodiment of the present specification.

With reference to FIG. 1, a display device 100 according to an embodiment of the present specification may include an image processor 161, a timing controller 162, a data driver 163, a scan driver 164, and a display panel PN.

The image processor 161 may output a data signal DATA, a data enable signal DE, and the like supplied from the outside.

In addition, for example, the image processor 161 may output one or more of a vertical synchronizing signal, a horizontal synchronizing signal, and a clock signal in addition to the data enable signal DE.

The timing controller 162 may receive the data signal DATA in addition to the data enable signal DE or the driving signals including the vertical synchronizing signal, the horizontal synchronizing signal, and the clock signal from the image processor 161. In addition, on the basis of the driving signal, the timing controller 162 may output a gate timing control signal GDC for controlling an operation timing of the scan driver 164 and output a data timing control signal DDC for controlling an operation timing of the data driver 163.

In response to the data timing control signal DDC supplied from the timing controller 162, the data driver 163 may sample and latch the data signal DATA supplied from the timing controller 162, convert the data signal DATA into a gamma reference voltage, and output the gamma reference voltage. The data driver 163 may output the data signal DATA through data lines DL1 to DLn. The data driver 163 may be provided in the form of an integrated circuit (IC).

In addition, the scan driver 164 may output the scan signal in response to the gate timing control signal GDC supplied from the timing controller 162. The scan driver 164 may output the scan signal through gate lines GL1 to GLm. The scan driver 164 may be provided in the form of an integrated circuit (IC) or formed on the display panel PN in a gate-in-panel (GIP) manner.

The display panel PN may display an image in response to the data signal DATA and the scan signal supplied from the data driver 163 and the scan driver 164.

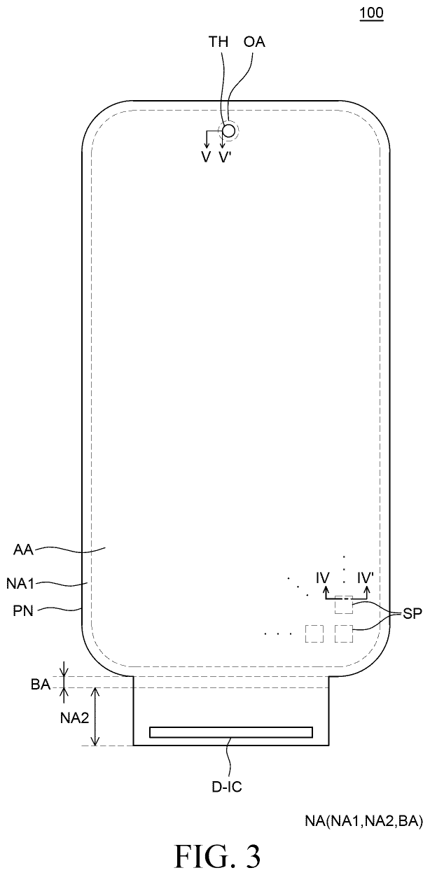

The display panel PN may include subpixels SP configured to display images. The display panel PN will be described in detail with reference to FIG. 3 to be described below.

For example, the subpixels SP may include a red subpixel, a green subpixel, and a blue subpixel or include a white subpixel, a red subpixel, a green subpixel, and a blue subpixel. The subpixel SP may have one or more different light-emitting areas depending on luminous properties.

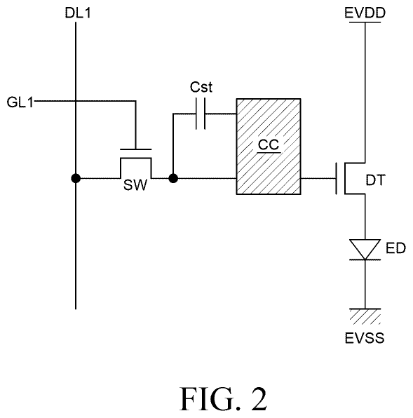

FIG. 2 is a view schematically illustrating a circuit configuration of the subpixel according to the embodiment of the present specification.

With reference to FIG. 2, one subpixel may include a switching transistor SW, a driving transistor DT, a capacitor Cst, a compensating circuit CC, and an organic light-emitting element ED.

For example, the switching transistor SW may perform a switching operation so that a data signal supplied through a first data line DL1 is stored, as a data voltage, in the capacitor Cst in response to a scan signal supplied through a first gate line GL1. In addition, for example, the driving transistor DT may operate such that a drive current flows between a first power line EVDD (high-potential voltage) and a second power line EVSS (low-potential voltage) in accordance with the data voltage stored in the capacitor Cst. In addition, the organic light-emitting element ED may operate to emit light in accordance with a drive current produced by the driving transistor DT.

The compensating circuit CC refers to a circuit added into the subpixel to compensate for a threshold voltage of the driving transistor DT or the like. The compensating circuit CC may include one or more transistors. The compensating circuit CC may have very various configurations depending on an external compensation method.

The subpixel illustrated in FIG. 2 has a 2T(Transistor)1C(Capacitor) structure including the switching transistor SW, the driving transistor DT, the capacitor Cst, and the light-emitting element ED. However, in case that the compensating circuit 135 is added, the subpixel may have various configurations such as 3T1C, 4T2C, 5T2C, 6T1C, 6T2C, 7T1C, 7T2C, or the like.

FIG. 3 is a top plan view of the display device according to the embodiment of the present specification. For convenience of description, FIG. 3 illustrates only the display panel PN and a data driver D-IC among various constituent elements of the display device 100.

The display panel PN may include a display area AA, an optical area OA surrounded by the display area AA and including a through-hole TH, and a non-display area NA extending from the display area AA.

The display area AA is an area of the display panel PN in which images are displayed.

A plurality of subpixels SP and a circuit for operating the plurality of subpixels SP may be disposed in the display area AA. The plurality of subpixels SP may be minimum units that constitute the display area AA. Display elements may be respectively disposed in the plurality of subpixels SP. For example, an organic light-emitting element including an anode, a light-emitting layer, and a cathode may be disposed in each of the plurality of subpixels SP. However, the present specification is not limited thereto. In addition, the circuit configured to operate the plurality of subpixels SP may include driving elements, lines, and the like. For example, the circuit may include a thin-film transistor, a storage capacitor, a gate line, a data line, and the like. However, the present specification is not limited thereto.

The optical area OA is an area disposed in the display area AA, surrounded by the display area AA, and having the through-hole TH. The through-hole TH may be disposed in the display area AA of the display panel PN, thereby reducing a bezel area, which is the non-display area NA, and maximizing the display area AA. A design product with the maximized display area AA maximizes a degree of screen immersion of a user, thereby improving an aesthetic appearance.

The through-hole TH may be formed to correspond to an electronic optical device. The electronic optical device may be a device that receives light having passed through the display panel PN and performs a predetermined function in response to the received light. Therefore, the electronic optical device may be disposed to overlap the through-hole TH of the display panel PN. For example, the electronic optical device may be configured as a camera or various sensors. However, the present specification is not limited thereto. The electronic optical device may include all devices that perform predetermined functions in response to the light. Meanwhile, because the electronic optical device is disposed below the display panel PN, the electronic optical device may not be visually recognized by the user. For example, in case that the electronic optical device is a camera, the camera is disposed on the rear surface of the display panel PN. However, the camera may capture an image of the front surface of the display device 100 instead of the rear surface of the display device 100.

FIG. 3 illustrates one through-hole TH. However, the present specification is not limited thereto. The number of through-holes TH may be variously provided. For example, two through-holes are disposed in the display area AA. A camera may be disposed in a first through-hole, and a distance detection sensor, a face recognition sensor, or a wide angle camera may be disposed in a second through-hole.

The non-display area NA is an area in which no image is displayed. Various lines, various circuits, and the like for operating the display elements in the display area AA are disposed in the non-display area NA. For example, the non-display area NA may include link lines for transmitting signals to the plurality of subpixels and the circuit in the display area AA. The non-display area NA may include gate-in-panel (GIP) lines or drive ICs such as the gate driver and the data driver.

The non-display area NA may be an area extending from the display area AA. However, the present specification is not limited thereto. The non-display area NA may be an area that surrounds the display area AA.

The non-display area NA includes a first non-display area NA1, a bending area BA, and a second non-display area NA2. The first non-display area NA1 is an area extending from the display area AA while surrounding the display area AA. The bending area BA may be an area extending from one side of the first non-display area NA1 and bent. The second non-display area NA2 may be an area extending from the bending area BA and disposed below the display area.

The first non-display area NA1 and the second non-display area NA2 may be areas disposed on the same plane as the display area AA or disposed in parallel with the display area AA and kept in a flat state. For example, the first non-display area NA1 may be disposed flat on the same plane as the display area AA, and the second non-display area NA2 may be disposed flat below the display area AA and disposed in parallel with the display area AA. Therefore, for example, the display area AA, the first non-display area NA1, and the second non-display area NA2 may be referred to as non-bending areas. However, the present specification is not limited thereto.

A drive IC D-IC may be disposed in the second non-display area NA2. The drive IC D-IC may be a data driver configured to provide the data signal to the plurality of subpixels SP. For example, a pad part may be disposed in the second non-display area NA2 in which the drive IC D-IC is disposed, and a printed circuit board electrically connected to the pad part may be further disposed and provide a signal to the drive IC D-IC. However, the present specification is not limited thereto.

Meanwhile, the drive IC D-IC may be disposed in the form of a chip-on panel (COP) at one side of the display panel PN and connected to the display panel PN. Alternatively, the drive IC D-IC may be provided in the form of a chip-on film (COF) disposed on a separate flexible film and connected to the display panel PN. However, the present specification is not limited thereto.

As the display panel PN is bent, the drive IC D-IC disposed in the second non-display area NA2 is disposed below the display area AA. For example, the drive IC D-IC and the printed circuit board, which is connected to the pad part of the display panel PN, may move to a rear surface side of the display panel PN and overlap the display area AA. Therefore, the circuit elements, such as the drive IC D-IC and the printed circuit board, may not be visually recognized when viewed from above the display panel PN. Therefore, a size of the non-display area NA, which is visually recognized from above the display panel PN, may be reduced, such that a narrow bezel may be implemented.

The display device 100 may further include various additional elements configured to generate various signals or operate a pixel in the display area AA. The additional elements for operating the pixel may include an inverter circuit, a multiplexer, an electrostatic discharge (ESD) circuit, and the like. The display device 100 may also include additional elements related to functions other than the function of operating the pixel. For example, the display device 100 may further include additional elements that provide a touch detection function, a user certification function (e.g., fingerprint recognition), a multi-level pressure detection function, a tactile feedback function, and the like. The above-mentioned additional elements may be positioned in the non-display area NA and/or an external circuit connected to a connection interface.

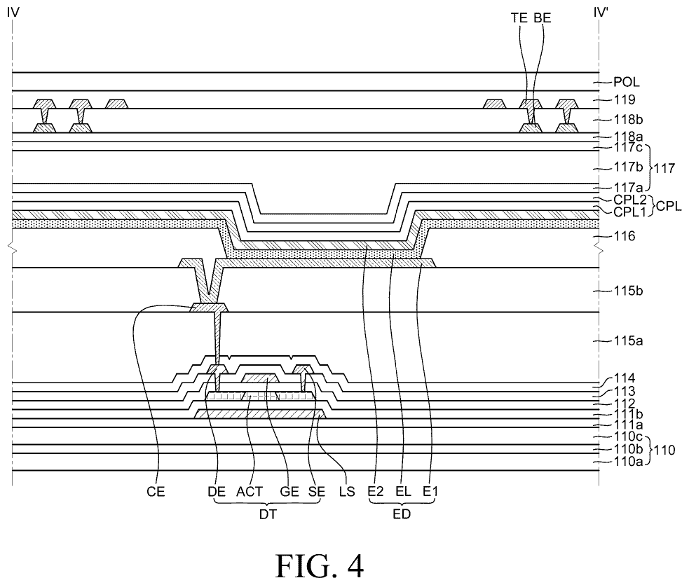

Hereinafter, a cross-sectional structure of the display device 100 will be described in more detail with reference to FIG. 4.

FIG. 4 is a cross-sectional view taken along line IV-IV′ in FIG. 3. For convenience of description, FIG. 4 illustrates only the constituent elements included in one adjacent subpixel SP disposed in the display area AA.

With reference to FIG. 4, a substrate 110 may be configured to support various constituent elements included in the display device 100, and the substrate 110 may be made of an insulating material. The substrate 110 may include a first substrate 110a, an insulation layer 110b, and a second substrate 110c. The insulation layer 110b may be disposed between the first substrate 110a and the second substrate 110c. As described above, the substrate 110 is configured by the first substrate 110a, the second substrate 110c, and the insulation layer 110b, which may suppress the moisture permeation. For example, the first substrate 110a and the second substrate 110c may each be a substrate made of polyimide (PI).

A first buffer layer 111a is disposed on the substrate 110. The first buffer layer 111a may reduce the permeation of moisture, oxygen, or impurities through the substrate 110. For example, the first buffer layer 111a may be configured as a single layer or multilayer made of silicon oxide (SiOx) or silicon nitride (SiNx). However, the present specification is not limited thereto.

A light-blocking layer LS is disposed in each of the plurality of subpixels on the first buffer layer 111a. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

A second buffer layer 111b is disposed on the substrate 110 and the light-blocking layer LS. The second buffer layer 111b may reduce the permeation of moisture or impurities through the substrate 110. For example, the second buffer layer 111b may be configured as a single layer or multilayer made of silicon oxide (SiOx) or silicon nitride (SiNx). However, the present specification is not limited thereto. However, the second buffer layer 111b may be excluded in accordance with the type of substrate 110 or the type of transistor. However, the present specification is not limited thereto.

The driving transistor DT is disposed in each of the plurality of subpixels SP on the second buffer layer 111b. The driving transistor DT is a transistor for controlling a drive current to be supplied to the light-emitting element ED.

The driving transistor DT includes the active layer ACT, a gate electrode GE, a source electrode SE, and a drain electrode DE.

The active layer ACT of the driving transistor DT may be disposed on the second buffer layer 111b. For example, the active layer ACT may be made of polysilicon (p-Si), amorphous silicon (a-Si), or oxide semiconductor. However, the present specification is not limited thereto.

A gate insulation layer 112 may be disposed on the active layer ACT. The gate insulation layer 112 is an insulation layer for insulating the active layer ACT and the gate electrode GE. The gate insulation layer 112 may be configured as a layer or multilayer made of silicon oxide (SiOx) or silicon nitride (SiNx).

In addition, the gate electrode GE of the driving transistor DT may be disposed on the gate insulation layer 112. The gate electrode GE is disposed on the gate insulation layer 112 and overlaps the active layer ACT. The gate electrode GE may be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

An interlayer insulation layer 113 may be disposed to cover the gate electrode GE. The interlayer insulation layer 113 may be an insulation layer for protecting components disposed below the interlayer insulation layer 113. The interlayer insulation layer 113 may be configured as a single layer or multilayer made of silicon oxide (SiOx) or silicon nitride (SiNx). However, the present specification is not limited thereto.

The source electrode SE and the drain electrode DE of the driving transistor DT may be disposed on the interlayer insulation layer 113.

The source electrode SE and the drain electrode DE may be respectively connected to one side and the other side of the active layer ACT through contact holes provided in the interlayer insulation layer 113 and the gate insulation layer 112. The source electrode SE and the drain electrode DE may each be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A portion of the active layer ACT, which overlaps the gate electrode GE, is a channel area. One of the source electrode SE and the drain electrode DE is connected to one side of the channel area of the active layer ACT, and the other of the source electrode SE and the drain electrode DE is connected to the other side of the channel area of the active layer ACT.

A passivation layer 114 may be disposed on the source electrode SE and the drain electrode DE. The passivation layer 114 may serve to protect the driving transistor DT and be configured as an inorganic layer, for example, silicon oxide (SiOx), silicon nitride (SiNx), or a multilayer thereof.

A first planarization layer 115a may be disposed on the passivation layer 114. The first planarization layer 115a may protect the driving transistor DT and planarize an upper portion of the driving transistor DT. The first planarization layer 115a may be configured as a single layer or multilayer and made of a photoresist or an acrylic-based organic material, for example. However, the present specification is not limited thereto.

A connection electrode CE may be disposed on the first planarization layer 115a.

The connection electrode CE may be connected to one of the source electrode SE and the drain electrode DE through a contact hole provided in the first planarization layer 115a.

A second planarization layer 115b may be disposed on the connection electrode CE. The second planarization layer 115b may be made of the same material as the first planarization layer 115a.

The light-emitting element ED including a first electrode E1, an organic layer EL, and a second electrode E2 may be positioned above the second planarization layer 115b.

Hereinafter, a layered structure of the light-emitting element ED will be described in detail.

The first electrode E1 may be disposed on the second planarization layer 115b. In this case, the first electrode E1 may be electrically connected to the connection electrode CE through a contact hole provided in the second planarization layer 115b. The first electrode E1 may be made of a metallic material.

For example, in case that the display device 100 is a top-emission type display device in which light emitted from the light-emitting element ED propagates toward an upper side of the substrate SUB on which the light-emitting element ED is disposed, the first electrode E1 may include a transparent conductive layer and a reflective layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

A bank 116 may be disposed to cover an end of the first electrode E1 and define a light-emitting area. A portion of the bank 116, which corresponds to the light-emitting area of the subpixel SP, may be opened. A part of the first electrode E1 may be exposed through the opened portion (hereinafter, referred to as an open area) of the bank 116. In this case, the bank 116 may be made of an inorganic insulating material such as silicon nitride (SiNx) or silicon oxide (SiOx), or an organic insulating material such as benzocyclobutene-based resin, acrylic resin, or imide-based resin. However, the present specification is not limited thereto.

The organic layer EL may be disposed on the bank 116. Therefore, the organic layer EL may be disposed on the first electrode E1 exposed through an open area of the bank 116. The organic layer EL may include a plurality of organic material layers.

The second electrode E2 may be disposed on the organic layer EL. For example, the second electrode E2 may include a transparent electrically conductive material that transmits light. For example, the second electrode may be made of at least one of indium-tin oxide (ITO) and indium-zinc oxide (IZO). However, the present specification is not limited thereto. In addition, the second electrode E2 may be disposed by using a semi-transparent electrically conductive material that transmits light. For example, the second electrode may be made of at least one of the alloys such as LiF/Al, CsF/Al, Mg:Ag, Ca/Ag, Ca:Ag, LiF/Mg:Ag, LiF/Ca/Ag, and LiF/Ca:Ag. However, the present specification is not limited thereto.

The light-emitting element ED may be formed by the first electrode E1, the organic layer EL, and the second electrode E2.

A capping layer CPL may be positioned above the light-emitting element ED. The capping layer CPL may assist in protecting the light-emitting element ED and efficiently discharging the light, which is emitted from the organic layer EL, to the outside.

The capping layer CPL may include a first capping layer CPL1 made of an organic material, and a second capping layer CPL2 made of an inorganic material.

For example, the first capping layer CPL1 made of an organic material may be made of any one or more materials selected from a group consisting of NPD (N,N-dinaphthyl-N,N′-diphenylbenzidine), TPD (N,N′-bis-(3-methylphenyl)-N,N′-bis-(phenyl)-benzidine), s-TAD, MTDATA (4,4′,4″-Tris(N-3-methylphenyl-N-phenyl-amino)-triphenylamine), Alq3 (tris(8-hydroxyquinolino) aluminum), PBD (2-(4-biphenylyl)-5-(4-tert-butylpheny)-1,3,4oxadiazole), TAZ, spiro-PBD, BAlq, SAlq, CBP (carbazole biphenyl), and mCP (1,3-bis (carbazol-9-yl)). However, the present specification is not limited thereto.

For example, the second capping layer CPL2 made of an inorganic material may include lithium fluoride (LiF), silicon oxide (SiOx), and silicon oxynitride (SiON). However, the present specification is not limited thereto.

An encapsulation unit 117 may be positioned above the capping layer CPL.

The encapsulation unit 117 may have a single-layer structure or a multilayer structure. For example, the encapsulation unit 117 may include a first encapsulation layer 117a, a second encapsulation layer 117b, and a third encapsulation layer 117c.

In this case, the first encapsulation layer 117a and the third encapsulation layer 117c may each be configured as an inorganic layer, and the second encapsulation layer 117b may each be configured as an organic layer. For example, the second encapsulation layer 117b may be referred to as an organic encapsulation layer. However, the present specification is not limited thereto.

Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the second electrode E2 and disposed to be closest to the light-emitting element ED. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the organic layer EL made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers. The second encapsulation layer 117b may serve to improve the planarization performance. For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present specification is not limited thereto.

The third encapsulation layer 117c may be formed above the substrate 110 having the second encapsulation layer 117b to cover a top surface and a side surface of each of the second encapsulation layer 117b and the first encapsulation layer 117a. In this case, the third encapsulation layer 117c may minimize or block the permeation of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

A touch detection part may be disposed above the encapsulation unit 117.

Specifically, the touch detection part may include a touch buffer layer 118a disposed on the encapsulation unit 117, a bridge electrode BE disposed on the touch buffer layer 118a, a touch interlayer insulation layer 118b disposed on the touch buffer layer 118a and the bridge electrode BE, and a plurality of touch electrodes TE disposed on the touch interlayer insulation layer 118b.

The touch buffer layer 118a may inhibit outside moisture, foreign substances, or a liquid chemical such as a developer or an etching liquid, which is used during a process of manufacturing the touch electrodes formed on the touch buffer layer 118a, from penetrating into the light-emitting element.

The plurality of touch electrodes TE may include a plurality of first touch electrodes extending in a first direction, and a plurality of second touch electrodes extending in a second direction intersecting the first direction.

For example, the plurality of first touch electrodes and the plurality of second touch electrodes may be disposed on the same layer. However, the plurality of second touch electrodes may be disposed to be separated from one another in the area in which the plurality of first touch electrodes and the plurality of second touch electrodes intersect. The plurality of second touch electrodes, which are separated from one another, may be connected by the bridge electrodes BE. The touch interlayer insulation layers 118b may be disposed between the plurality of second touch electrodes and the bridge electrodes BE.

A protective layer 119 may be disposed to cover the touch detection part. The protective layer 119 may be configured as an organic insulation layer. The protective layer 119 may protect the touch detection part and planarize an upper portion of the touch detection part. In addition, the protective layer 119 may suppress a level difference on an upper layer of the display device 100, thereby improving the visibility of the display device 100. For example, the protective layer 119 may include an organic material such as acrylic resin, epoxy resin, phenolic resin, polyamide resin, and polyimide resin.

A polarizing layer POL may be disposed on the protective layer 119.

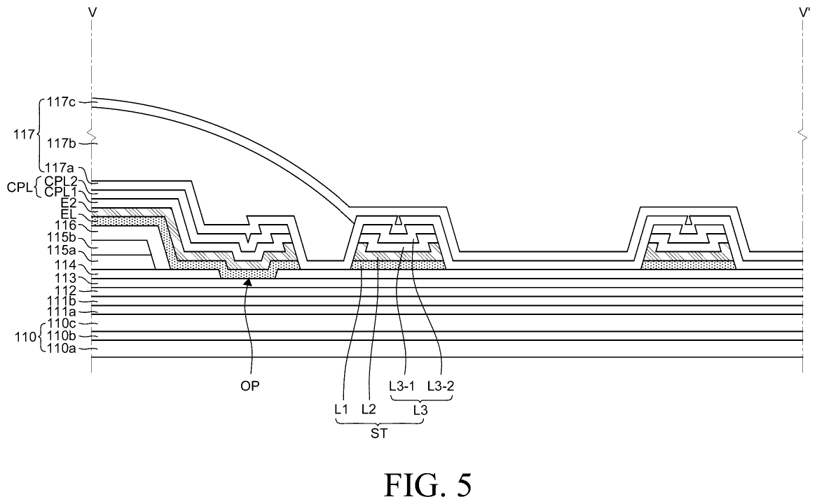

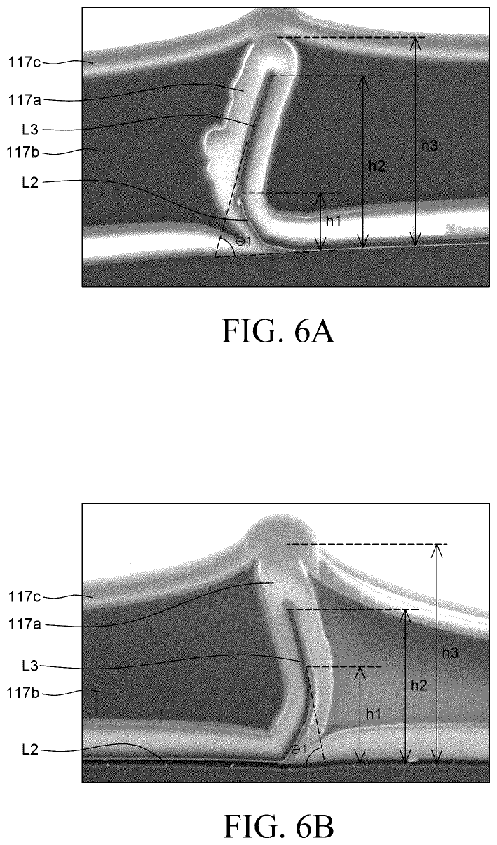

Hereinafter, a cross-sectional structure of the optical area OA will be described in more detail with reference to FIGS. 5 to 6B.

FIG. 5 is a cross-sectional view taken along line V-V′ in FIG. 3. FIGS. 6A and 6B are SEM images of a stopper according to the embodiment of the present specification. For convenience of description, FIG. 5 illustrates only the constituent elements disposed in the optical area OA among various constituent elements of the display device 100.

With reference to FIGS. 3 to 6B together, at least one stopper ST may be disposed in the optical area OA. At least one stopper ST may include a first layer L1 disposed on the same layer as the organic layer EL and made of the same material as the organic layer EL, a second layer L2 disposed on the first layer L1, disposed on the same layer as the second electrode E2, and made of the same material as the second electrode E2, and a third layer L3 disposed on the second layer L2, disposed on the same layer as the capping layer CPL, and made of the same material as the capping layer CPL. For example, the third layer L3 may include a 3-1 layer L3-1 disposed on the same layer as the first capping layer CPL1 and made of the same material as the first capping layer CPL1, and a 3-2 layer L3-2 disposed on the 3-1 layer L3-1, disposed on the same layer as the second capping layer CPL2, and made of the same material as the second capping layer CPL2.

At least one stopper ST may be formed by irradiating a partial area of the optical area OA with laser beams. For example, the organic layer, the second electrode, the first capping layer, and the second capping layer, which extend from the display area AA, may be disposed in the optical area OA. In this case, at least a partial area of the optical area OA may be irradiated with laser beams.

A picosecond laser or a femtosecond laser may be used as the laser. However, the present disclosure is not limited thereto. The laser refers to a device that amplifies light generated by applying energy to a particular material and uses light induced and emitted. The laser beams have the same characteristics as radio waves and have directionality of monochromatic light. Therefore, the laser is used for communication, medical, or industrial purposes. A pattern may be easily formed on a desired portion or a particular site may be easily removed by using the laser. The laser utilizes energy to form or remove patterns. When the energy of the laser is emitted onto the object, heat energy may melt an object to form patterns.

The organic layer may be melted and removed in the area of the optical area OA irradiated with laser beams, and the second electrode, the first capping layer, and the second capping layer disposed above the organic layer may be torn together with the organic layer. In addition, in an area of the optical area OA that is not irradiated with laser beams, the organic layer, the second electrode, the first capping layer, and the second capping layer remain, such that at least one stopper ST including the first layer L1, the second layer L2, and the third layer L3 may be formed.

In the display device 100 according to the embodiment of the present specification, two opposite ends of the second layer L2 may have shapes curved upward as the second electrode is torn together with the organic layer in the area irradiated with laser beams. Specifically, the two opposite ends of the second layer L2 included in at least one stopper ST may be curved toward the inside of at least one stopper ST. For example, the two opposite ends of the second layer L2 may have shapes curved upward by a first height h1 from a bottom surface of at least one stopper ST, e.g., a top surface of the passivation layer 114 or a top surface of the first layer L1.

In addition, because the second layer L2 has a shape curved toward the inside of at least one stopper ST, the third layer L3, which is disposed on the second layer L2, and the second layer L2 may be formed in the same aspect. Specifically, the third layer L3, which includes the 3-1 layer L3-1 and the 3-2 layer L3-2, may also be curved toward the inside of at least one stopper ST along the shape of the second layer L2. For example, the third layer L3 may have a shape curved upward by a second height h2 along the shape of the second layer L2 from the bottom surface of at least one stopper ST, e.g., the top surface of the passivation layer 114 or the top surface of the first layer L1.

In this case, an angle θ1 defined each of the second layer L2 and the third layer L3 with respect to the first layer L1 in at least one stopper ST may be less than 90 degrees, as illustrated in FIGS. 6A and 6B. For example, FIG. 6A illustrates a left side of at least one stopper ST, and FIG. 6B illustrates a right side of at least one stopper ST.

In the display device 100 according to the embodiment of the present specification, the second layer L2 may be a trigger from which the third layer L3 is curved upward. Therefore, the two opposite ends of at least one stopper ST may have shapes curved upward. The height and the angle θ1 of at least one stopper ST may be adjusted in accordance with a thickness of the 3-1 layer L3-1 and a thickness of the 3-2 layer L3-2. However, the present specification is not limited thereto. The height and the angle θ1 of at least one stopper ST may also be adjusted in accordance with an interval between the areas irradiated with laser power or laser beams. Therefore, the shape of at least one stopper ST disposed in the optical area OA may be controlled.

In the display device 100 according to the embodiment of the present specification, the two opposite ends of at least one stopper ST have the shapes curved upward, such that the second encapsulation layer 117b may be disposed to adjoin a side surface of at least one stopper ST in the optical area OA. That is, a flow of the second encapsulation layer 117b constituting the encapsulation unit 117 may be controlled by at least one stopper ST. At least one stopper ST may have a height for blocking a flow of the second encapsulation layer 117b. In addition, at least one stopper ST may be provided as a plurality of stoppers ST, e.g., two or more stoppers ST.

In addition, the first encapsulation layer 117a may cover an upper side of at least one stopper ST. For example, in the area that overlaps at least one stopper ST, the first encapsulation layer 117a may be disposed at a third height h3 from the bottom surface of at least one stopper ST, e.g., the top surface of the passivation layer 114 or the top surface of the first layer L1. Therefore, the flow of the second encapsulation layer 117b may be controlled by the third height h3, i.e., a height made by adding up the height of at least one stopper ST and a thickness of the first encapsulation layer 117a. Therefore, as the thickness of the first encapsulation layer 117a increases, the flow of the second encapsulation layer 117b may at least be more easily controlled.

In addition, selectively as necessary, the second organic layer 117b according to the present specification may be applied, and then an ashing process may be further performed on the second organic layer 117b. For example, even though the second organic layer 117b is not controlled by the stopper ST disposed to be closest to the display area AA, the second organic layer 117b may be cut by the ashing process, such that the flow of the second organic layer 117b may be more easily controlled by at least one stopper ST.

Meanwhile, an opening portion OP may be formed in a part of the insulation layer in the display area AA adjacent to the optical area OA. For example, the passivation layer 114 may include the opening portion OP.

For example, with reference to FIGS. 3 and 5 together, the through-hole TH may crack when the substrate 110 is cut to form the through-hole TH in the optical area OA. Alternatively, when the camera or sensor is assembled to the through-hole TH, cracks may occur because of interference. In case that the crack formed in the through-hole TH propagates to the display area AA through the plurality of inorganic insulation layers, a line defect may occur, or a dark spot may occur at an edge of the through-hole TH. Further, a growing dark spot (GDS) defect may occur in which the formed dark spot is gradually enlarged.

In the display device 100 according to the embodiment of the present specification, some of the plurality of insulation layers disposed in the optical area OA, e.g., the passivation layer 114 is included in the opening portion OP. Therefore, even though the through-hole TH cracks, a propagation route of the crack may be blocked, which may suppress a problem caused by the crack.

Although not illustrated, selectively as necessary, a dam may be further disposed in an area adjacent to the through-hole TH. For example, the dam may be provided in the form of a closed loop that surrounds the through-hole TH and further control the flow of the second encapsulation layer 117b to the through-hole TH. For example, in case that the dam is further included, the dam may be disposed on the same layer as the second planarization layer 115b and the bank 116 and made of the same material as the second planarization layer 115b and the bank 116.

A method of irradiating a part of the organic layer disposed in the optical area with laser beams has been used to disconnect the organic layer of the light-emitting element in the optical area. In this case, in the area irradiated with laser beams, the organic layer may be melted and removed, and the second electrode disposed above the organic layer may also be torn together with the organic layer and removed. However, there are problems in that burrs are formed as the two opposite ends of the second electrode remaining in an area adjacent to the area irradiated with laser beams are curled upward. In addition, in order to block a flow of the organic encapsulation layer constituting the encapsulation unit in the optical area, a plurality of dams are disposed in an area, which is adjacent to the display area, and an area, which is adjacent to the through-hole, in the optical area. For this reason, there is a problem in that an area occupied by the optical area increases because at least two or more dams are disposed in the optical area.

Therefore, in the display device 100 according to the embodiment of the present specification, at least one stopper ST in the optical area OA blocks the flow of the second encapsulation layer 117b, such that the dam disposed in the area adjacent to the display area AA may be excluded. Therefore, it is possible to reduce the area of the optical area OA.

In addition, it is possible to disconnect the organic layer EL by irradiating the optical area OA with laser beams to form at least one stopper ST. Therefore, it is possible to block the route of the permeation of moisture or oxygen into the light-emitting element ED in the display area AA along the organic layer EL in the optical area OA.

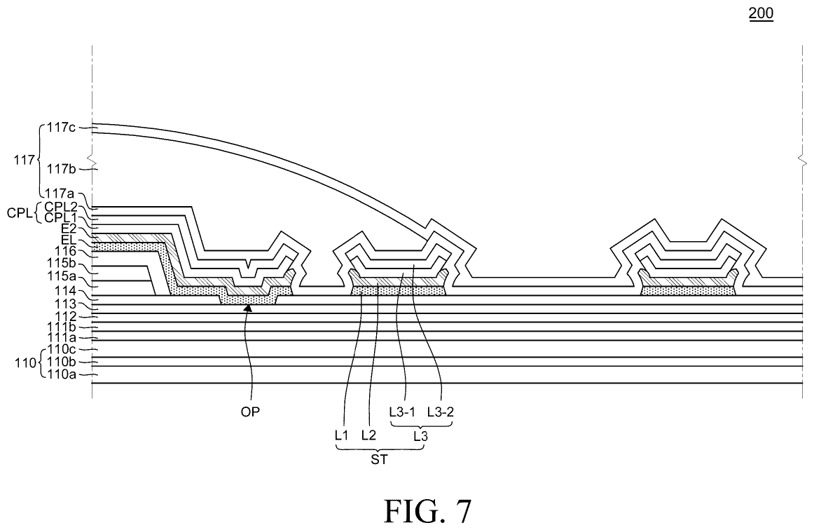

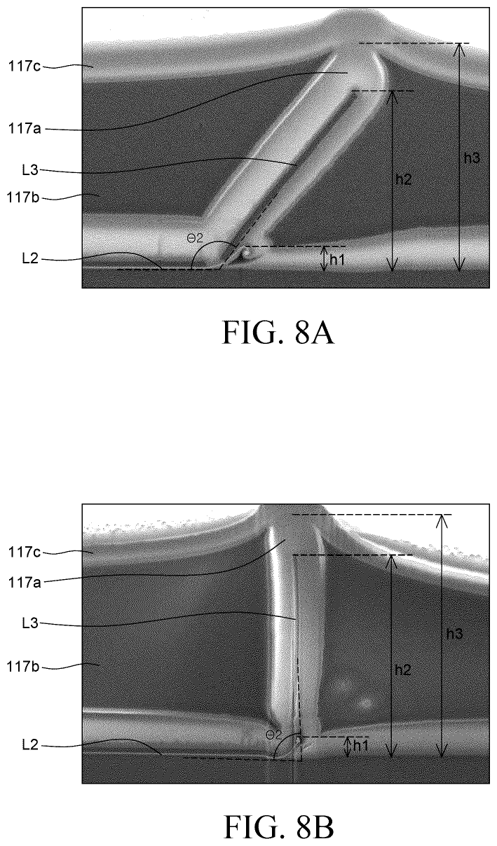

FIG. 7 is a cross-sectional view of a display device according to another embodiment of the present specification. FIGS. 8A and 8B are SEM images of a stopper according to another embodiment of the present specification. The configuration in FIG. 7 is substantially identical to the configuration in FIGS. 1 to 6B, except for a shape of the stopper ST. Therefore, for convenience of description, a repeated description will be omitted, except for the stopper ST.

With reference to FIGS. 3 to 8B again, in a display device 200 according to another embodiment of the present specification, at least one stopper ST may be disposed in the optical area OA.

At least one stopper ST may be formed by irradiating a partial area of the optical area OA with laser beams. For example, the organic layer, the second electrode, the first capping layer, and the second capping layer, which extend from the display area AA, may be disposed in the optical area OA. In this case, at least a partial area of the optical area OA may be irradiated with laser beams.

The organic layer may be melted and removed in the area of the optical area OA irradiated with laser beams, and the second electrode, the first capping layer, and the second capping layer disposed above the organic layer may be torn together with the organic layer. In addition, in an area of the optical area OA that is not irradiated with laser beams, the organic layer, the second electrode, the first capping layer, and the second capping layer remain, such that at least one stopper ST including the first layer L1, the second layer L2, and the third layer L3 may be formed.

In the display device 200 according to another embodiment of the present specification, two opposite ends of the second layer L2 may have shapes curved upward as the second electrode is torn together with the organic layer in the area irradiated with laser beams. Specifically, the two opposite ends of the second layer L2 included in at least one stopper ST may be curved in a vertical direction or curved to the outside of at least one stopper ST. For example, the two opposite ends of the second layer L2 may have shapes curved upward by the first height h1 from the bottom surface of at least one stopper ST, e.g., the top surface of the passivation layer 114 or the top surface of the first layer L1.

In addition, because the second layer L2 has a shape curved toward the outside of at least one stopper ST, the third layer L3, which is disposed on the second layer L2, and the second layer L2 may be formed in the same aspect. Specifically, the third layer L3, which includes the 3-1 layer L3-1 and the 3-2 layer L3-2, may also be curved in the vertical direction or curved to the outside of at least one stopper ST along the shape of the second layer L2. For example, the third layer L3 may have a shape curved upward by the second height h2 along the shape of the second layer L2 from the bottom surface of at least one stopper ST, e.g., the top surface of the passivation layer 114 or the top surface of the first layer L1. In this case, as illustrated in FIGS. 8A and 8B, an angle θ2 defined each of the second layer L2 and the third layer L3 with respect to the first layer L1 in at least one stopper ST may be 90 degrees or more, e.g., more than 90 degrees. For example, in case that laser beams with relatively lower laser power are emitted in comparison with the display device 100 in FIGS. 1 to 6B, the two opposite ends of at least one stopper ST may be curved in the vertical direction or curved to the outside of at least one stopper ST, as illustrated in FIGS. 8A and 8B.

In the display device 200 according to another embodiment of the present specification, the second layer L2 may be a trigger from which the third layer L3 is curved upward. Therefore, the two opposite ends of at least one stopper ST may have shapes curved upward. The height and the angle θ2 of at least one stopper ST may be adjusted in accordance with the thickness of the 3-1 layer L3-1 and the thickness of the 3-2 layer L3-2. However, the present specification is not limited thereto. The height and the angle θ2 of at least one stopper ST may also be adjusted in accordance with the interval between the areas irradiated with laser power or laser beams. Therefore, the shape of at least one stopper ST disposed in the optical area OA may be controlled.

In the display device 200 according to another embodiment of the present specification, the two opposite ends of at least one stopper ST have the shapes curved upward, such that the second encapsulation layer 117b may be disposed to adjoin the side surface of at least one stopper ST in the optical area OA. That is, a flow of the second encapsulation layer 117b constituting the encapsulation unit 117 may be controlled by at least one stopper ST. At least one stopper ST may have a height for blocking a flow of the second encapsulation layer 117b. In addition, at least one stopper ST may be provided as a plurality of stoppers ST, e.g., two or more stoppers ST.

In addition, the first encapsulation layer 117a may cover the upper side of at least one stopper ST. For example, in the area that overlaps at least one stopper ST, the first encapsulation layer 117a may be disposed at the third height h3 from the bottom surface of at least one stopper ST, e.g., the top surface of the passivation layer 114 or the top surface of the first layer L1. Therefore, the flow of the second encapsulation layer 117b may be controlled by the third height h3, i.e., the height made by adding up the height of at least one stopper ST and the thickness of the first encapsulation layer 117a. Therefore, as the thickness of the first encapsulation layer 117a increases, the flow of the second encapsulation layer 117b may at least be more easily controlled.

In addition, selectively as necessary, the second organic layer 117b according to the present specification may be applied, and then an ashing process may be further performed on the second organic layer 117b. However, the present specification is not limited thereto. In this case, the flow of the second organic layer 117b may be more easily controlled by at least one stopper ST.

In the display device 200 according to another embodiment of the present specification, at least one stopper ST in the optical area OA blocks the flow of the second encapsulation layer 117b, such that the dam disposed in the area adjacent to the display area AA may be excluded. Therefore, it is possible to reduce the area of the optical area OA.

In addition, it is possible to disconnect the organic layer EL by irradiating the optical area OA with laser beams to form at least one stopper ST. Therefore, it is possible to block the route of the permeation of moisture or oxygen into the light-emitting element ED in the display area AA along the organic layer EL in the optical area OA.

The exemplary embodiments of the present disclosure can also be described as follows:

According to an aspect of the present disclosure, a display device includes a substrate including a display area, an optical area disposed in the display area and including a through-hole, and a non-display area configured to surround the display area, a plurality of light-emitting elements disposed in the display area on the substrate and including a first electrode, an organic layer on the first electrode, and a second electrode on the organic layer, a capping layer configured to cover the plurality of light-emitting elements, an encapsulation unit configured to cover the capping layer, and at least one stopper disposed in the optical area on the substrate, in which at least one stopper includes a first layer disposed on the same layer as the organic layer and made of the same material as the organic layer, a second layer disposed on the first layer, disposed on the same layer as the second electrode, and made of the same material as the second electrode, and a third layer disposed on the second layer, disposed on the same layer as the capping layer, and made of the same material as the capping layer.

The encapsulation unit may comprise a first encapsulation layer disposed on the capping layer and made of an inorganic material, a second encapsulation layer disposed on the first encapsulation layer and made of an organic material, and a third encapsulation layer disposed on the second encapsulation layer and made of an inorganic material, and the second encapsulation layer may be disposed to adjoin a side surface of at least one stopper in the optical area.

The capping layer comprising a first capping layer made of an organic material, and a second capping layer disposed on the first capping layer and made of an inorganic material, and the third layer may comprise a 3-1 layer disposed on the same layer as the first capping layer and made of the same material as the first capping layer, and a 3-2 layer disposed on the 3-1 layer, disposed on the same layer as the second capping layer, and made of the same material as the second capping layer.

Two opposite ends of at least one stopper may have shapes curved upward.

Two opposite ends of the second layer included in at least one stopper may be curved toward the inside of at least one stopper.

The third layer may be curved toward the inside of at least one stopper along a shape of the second layer.

An angle defined each of the second layer and the third layer with respect to the first layer may be less than 90 degrees.

Two opposite ends of the second layer included in at least one stopper may be curved toward the outside of at least one stopper.

The third layer may be curved toward the outside of at least one stopper along a shape of the second layer.

An angle defined each of the second layer and the third layer with respect to the first layer may be 90 degrees or more.

Two opposite ends of the second layer have shapes curved upward by a first height from the first layer, the third layer is curved upward by a second height from the first layer along a shape of the second layer, and the first encapsulation layer may be disposed at a third height from the first layer to cover the second layer in an area that overlaps at least one stopper.

According to an another aspect of the present disclosure, a display device includes a substrate including a display area, an optical area disposed in the display area and including a through-hole, and a non-display area configured to surround the display area, a plurality of light-emitting elements disposed in the display area on the substrate and including a first electrode, an organic layer on the first electrode, and a second electrode on the organic layer, a capping layer configured to cover the plurality of light-emitting elements, and at least one stopper disposed in the optical area on the substrate, in which at least one stopper includes a first layer disposed on the same layer as the organic layer and made of the same material as the organic layer, a second layer disposed on the first layer, disposed on the same layer as the second electrode, and made of the same material as the second electrode, and a third layer disposed on the second layer, disposed on the same layer as the capping layer, and made of the same material as the capping layer, and in which two opposite ends of at least one stopper have shapes curved upward.

The display device may further comprise an encapsulation unit disposed on the capping layer, the encapsulation unit comprises a first encapsulation layer made of an inorganic material, a second encapsulation layer disposed on the first encapsulation layer and made of an organic material, and a third encapsulation layer disposed on the second encapsulation layer and made of an inorganic material, and the second encapsulation layer may be disposed to adjoin a side surface of at least one stopper in the optical area.

The capping layer comprising a first capping layer made of an organic material, and a second capping layer disposed on the first capping layer and made of an inorganic material, and the third layer may comprise a 3-1 layer disposed on the same layer as the first capping layer and made of the same material as the first capping layer, and a 3-2 layer disposed on the 3-1 layer, disposed on the same layer as the second capping layer, and made of the same material as the second capping layer.

Two opposite ends of the second layer included in at least one stopper may be curved toward the inside of at least one stopper.

The third layer may be curved toward the inside of at least one stopper along a shape of the second layer.

Two opposite ends of the second layer included in at least one stopper may be curved toward the outside of at least one stopper.

The third layer may be curved toward the outside of at least one stopper along a shape of the second layer.

Two opposite ends of the second layer have shapes curved upward by a first height from the first layer, the third layer is curved upward by a second height from the first layer along a shape of the second layer, and the first encapsulation layer may be disposed at a third height from the first layer to cover the second layer in an area that overlaps at least one stopper.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate comprising a display area, an optical area disposed in the display area and comprising a through-hole, and a non-display area adjacent to the display area;
a plurality of light-emitting elements disposed in the display area on the substrate and comprising a first electrode, an organic layer on the first electrode, and a second electrode on the organic layer;
a capping layer configured to cover the plurality of light-emitting elements;
an encapsulation unit configured to cover the capping layer; and
at least one stopper disposed in the optical area on the substrate,
wherein at least one stopper comprises:
a first layer on the same layer as the organic layer and made of the same material as the organic layer;
a second layer on the first layer, disposed on the same layer as the second electrode, and made of the same material as the second electrode; and
a third layer on the second layer, disposed on the same layer as the capping layer, and made of the same material as the capping layer.

2. The display device of claim 1, wherein the encapsulation unit comprises:
a first encapsulation layer on the capping layer and made of an inorganic material;
a second encapsulation layer on the first encapsulation layer and made of an organic material; and
a third encapsulation layer on the second encapsulation layer and made of an inorganic material, and
wherein the second encapsulation layer is disposed to adjoin a side surface of at least one stopper in the optical area.

3. The display device of claim 1, wherein the capping layer comprises:
a first capping layer made of an organic material; and
a second capping layer on the first capping layer and made of an inorganic material, and
wherein the third layer comprises:
a 3-1 layer on the same layer as the first capping layer and made of the same material as the first capping layer; and
a 3-2 layer on the 3-1 layer, disposed on the same layer as the second capping layer, and made of the same material as the second capping layer.

4. The display device of claim 3, wherein two opposite ends of at least one stopper have shapes curved upward.

5. The display device of claim 4, wherein two opposite ends of the second layer included in at least one stopper are curved toward the inside of at least one stopper.

6. The display device of claim 5, wherein the third layer is curved toward the inside of at least one stopper along a shape of the second layer.

7. The display device of claim 6, wherein an angle defined each of the second layer and the third layer with respect to the first layer is less than 90 degrees.

8. The display device of claim 4, wherein two opposite ends of the second layer included in at least one stopper are curved toward the outside of at least one stopper.

9. The display device of claim 8, wherein the third layer is curved toward the outside of at least one stopper along a shape of the second layer.

10. The display device of claim 9, wherein an angle defined each of the second layer and the third layer with respect to the first layer is 90 degrees or more.

11. The display device of claim 4, wherein two opposite ends of the second layer have shapes curved upward by a first height from the first layer, the third layer is curved upward by a second height from the first layer along a shape of the second layer, and the first encapsulation layer is disposed at a third height from the first layer to cover the second layer in an area that overlaps at least one stopper.

12. A display device comprising:
a substrate comprising a display area, an optical area disposed in the display area and comprising a through-hole, and a non-display area configured to surround the display area;
a plurality of light-emitting elements disposed in the display area on the substrate and comprising a first electrode, an organic layer on the first electrode, and a second electrode on the organic layer;
a capping layer configured to cover the plurality of light-emitting elements; and
at least one stopper disposed in the optical area on the substrate,
wherein at least one stopper comprises:
a first layer on the same layer as the organic layer and made of the same material as the organic layer;
a second layer on the first layer, disposed on the same layer as the second electrode, and made of the same material as the second electrode; and
a third layer on the second layer, disposed on the same layer as the capping layer, and made of the same material as the capping layer, and
wherein two opposite ends of at least one stopper have shapes curved upward.

13. The display device of claim 12, further comprising:
an encapsulation unit on the capping layer,
wherein the encapsulation unit comprises:
a first encapsulation layer made of an inorganic material;
a second encapsulation layer on the first encapsulation layer and made of an organic material; and
a third encapsulation layer on the second encapsulation layer and made of an inorganic material, and
wherein the second encapsulation layer is disposed to adjoin a side surface of at least one stopper in the optical area.

14. The display device of claim 12, wherein the capping layer comprises:
a first capping layer made of an organic material; and
a second capping layer on the first capping layer and made of an inorganic material, and
wherein the third layer comprises:
a 3-1 layer on the same layer as the first capping layer and made of the same material as the first capping layer; and
a 3-2 layer on the 3-1 layer, disposed on the same layer as the second capping layer, and made of the same material as the second capping layer.

15. The display device of claim 14, wherein two opposite ends of the second layer included in at least one stopper are curved toward the inside of at least one stopper.

16. The display device of claim 15, wherein the third layer is curved toward the inside of at least one stopper along a shape of the second layer.

17. The display device of claim 14, wherein two opposite ends of the second layer included in at least one stopper are curved toward the outside of at least one stopper.

18. The display device of claim 17, wherein the third layer is curved toward the outside of at least one stopper along a shape of the second layer.

19. The display device of claim 14, wherein two opposite ends of the second layer have shapes curved upward by a first height from the first layer, the third layer is curved upward by a second height from the first layer along a shape of the second layer, and the first encapsulation layer is disposed at a third height from the first layer to cover the second layer in an area that overlaps at least one stopper.

20. A display device comprising:
a substrate including a display area, an optical area disposed within the display area, and a non-display area;
a plurality of light-emitting elements disposed in the display area, each including a first electrode, a second electrode, and an organic layer between the first electrode and the second electrode;
a capping layer on the light-emitting elements; and
at least one stopper disposed in the optical area and formed of:
a first layer made of a same material and on a same layer as the organic layer;
a second layer made of a same material and on a same layer as the second electrode; and
a third layer made of a same material and on a same layer as the capping layer.

21. The display device of claim 20, comprising: an encapsulation unit on the capping layer, the encapsulation unit including a first inorganic layer, a second organic layer, and a third inorganic layer; and
a through-hole in the optical area.

22. The display device of claim 21, wherein the at least one stopper is configured to:
disconnect an organic emission path surrounding the through-hole, and
redirect lateral flow of the encapsulation unit toward the through-hole.

23. The display device of claim 20, wherein two opposite ends of the at least one stopper have shapes curved upward.

24. The display device of claim 20, wherein the second layer of the at least one stopper has ends curved toward the inside of the at least one stopper, and
wherein the third layer follows the curvature of the second layer.

25. The display device of claim 24, wherein an angle defined by each of the second and third layers relative to the first layer is less than 90 degrees.

26. The display device of claim 20, wherein the second layer of the at least one stopper has ends curved toward the outside of the at least one stopper, and
wherein the third layer follows the curvature of the second layer.

27. The display device of claim 26, wherein an angle defined by each of the second and third layers relative to the first layer is at least 90 degrees.

28. The display device of claim 20, wherein no dam structure is disposed in the optical area.

29. The display device of claim 21, wherein at least one stopper has a height sufficient to block lateral flow of the encapsulation unit into the through-hole.
